(19) United States
(12) Patent Application Publication
(10) Pub. No.: US 2026/0006843 A1
(43) Pub. Date: Jan. 1, 2026

(54) L-SHAPED STACKED FIELD EFFECT TRANSISTOR

(71) Applicant: International Business Machines Corporation, Armonk, NY (US)

(72) Inventors: Chen Zhang, Santa Clara, CA (US); Ruilong Xie, Niskayuna, NY (US); Abir Shadman, Albany, NY (US); Shahrukh Khan, Sandy Hook, CT (US); Junli Wang, Slingerlands, NY (US)

(21) Appl. No.: 18/760,076

(22) Filed: Jul. 1, 2024

(51) Int. Cl. H01L 29/423; H01L 27/092; H01L 29/06; H01L 29/66; H01L 29/775; H01L 29/786

(52) U.S. Cl. CPC H10D 30/6735; H10D 30/014; H10D 30/43; H10D 30/6757; H10D 62/115; H10D 62/121; H10D 84/853

(57) ABSTRACT

Embodiments of the present disclosure are directed to L-shaped stacked field effect transistor (SFET) processing methods and resulting structures having separate top and bottom self-aligned contact (SAC) caps. In a non-limiting embodiment, a first nanosheet stack having a first nanosheet and a second nanosheet stack having a second nanosheet are vertically stacked. A gate is formed around a channel region of the first nanosheet and a channel region of the second nanosheet. The gate includes a first portion recessed to a first gate height and a second portion recessed to a second gate height less than the first gate height. A bottom self-aligned contact cap is formed on the second portion of the gate and a top self-aligned contact cap is formed on the first portion of the gate.

### BACKGROUND

The present disclosure generally relates to fabrication methods and resulting structures for semiconductor devices, and more specifically, to processing methods and resulting structures for an L-shaped stacked field effect transistor (SFET) with separate top and bottom self-aligned contact (SAC) caps.

Known metal oxide semiconductor field effect transistor (MOSFET) fabrication techniques include process flows for constructing planar field effect transistors (FETs). A planar FET includes a substrate (also referred to as a silicon slab); a gate formed over the substrate; source and drain regions formed on opposite ends of the gate; and a channel region near the surface of the substrate under the gate. The channel region electrically connects the source region to the drain region while the gate controls the current in the channel. The gate voltage controls whether the path from drain to source is an open circuit (“off”) or a resistive path (“on”).

In recent years, research has been devoted to the development of nonplanar transistor architectures. For example, GAA transistors (also referred to as nanosheet FETs and nanowire FETs) include a non-planar architecture that provides increased device density and some increased performance over lateral devices. In nanosheet FETs, in contrast to conventional planar FETs, the channel is implemented as a plurality of stacked and spaced-apart nanosheets. The gate stack wraps around the full perimeter of each nanosheet, thus enabling fuller depletion in the channel region, and also reducing short-channel effects due to steeper subthreshold swing (SS) and smaller drain induced barrier lowering (DIBL). As MOSFET fabrication continues to develop, stacked FET architectures are being investigated to meet aggressive gate length (Lg) scaling requirements and current drive capabilities. In a stacked FET, two (or more) FETs are vertically stacked over a substrate to reduce the overall device footprint.

### SUMMARY

Embodiments are directed to a method for forming an L-shaped stacked semiconductor device having separate top and bottom self-aligned contact (SAC) caps. A non-limiting example of the method includes forming a first nanosheet stack having a first nanosheet and vertically stacking a second nanosheet stack having a second nanosheet over the first nanosheet stack. A gate is formed around a channel region of the first nanosheet and a channel region of the second nanosheet. The gate includes a first portion recessed to a first gate height and a second portion recessed to a second gate height less than the first gate height. A bottom self-aligned contact cap is formed on the second portion of the gate and a top self-aligned contact cap is formed on the first portion of the gate.

In some embodiments, the first nanosheet stack further includes one or more additional nanosheets, and the second nanosheet stack further includes one or more additional nanosheets.

In some embodiments, the method includes forming a dielectric isolation structure between the first nanosheet stack and the second nanosheet stack.

In some embodiments, the method includes forming a bottom source or drain region in direct contact with sidewalls of the first nanosheet and forming a top source or drain region in direct contact with sidewalls of the second nanosheet. In some embodiments, the bottom source or drain region is electrically isolated from the top source or drain region. In some embodiments, the first source or drain region includes a first doping type and the second source or drain region includes a second doping type opposite the first doping type.

In some embodiments, the method includes forming a bottom contact on a surface of the bottom source or drain region and forming a top contact on a surface of the top source or drain region.

In some embodiments, the gate is recessed to define a disjoint L-shaped cavity. In some embodiments, the method includes forming a disjoint L-shaped isolation structure in the disjoint L-shaped cavity. In some embodiments, disjoint portions of the disjoint L-shaped isolation structure are in direct contact with the dielectric isolation structure.

Embodiments are directed to a semiconductor structure. A non-limiting example of the semiconductor structure includes a first nanosheet stack having a first nanosheet and a second nanosheet stack having a second nanosheet vertically stacked over the first nanosheet stack. A gate is positioned around a channel region of the first nanosheet and a channel region of the second nanosheet. The gate includes a first portion recessed to a first gate height and a second portion recessed to a second gate height less than the first gate height. A bottom self-aligned contact cap is positioned on the second portion of the gate and a top self-aligned contact cap is formed on the first portion of the gate.

In some embodiments, the first nanosheet stack further includes one or more additional nanosheets, and the second nanosheet stack further includes one or more additional nanosheets.

In some embodiments, a dielectric isolation structure is positioned between the first nanosheet stack and the second nanosheet stack.

In some embodiments, a bottom source or drain region is formed in direct contact with sidewalls of the first nanosheet and a top source or drain region is formed in direct contact with sidewalls of the second nanosheet. In some embodiments, the bottom source or drain region is electrically isolated from the top source or drain region. In some embodiments, the first source or drain region includes a first doping type and the second source or drain region includes a second doping type opposite the first doping type.

In some embodiments, a bottom contact is formed on a surface of the bottom source or drain region and a top contact is formed on a surface of the top source or drain region.

In some embodiments, the gate is recessed to define a disjoint L-shaped cavity. In some embodiments, a disjoint L-shaped isolation structure is formed in the disjoint L-shaped cavity. In some embodiments, disjoint portions of the disjoint L-shaped isolation structure are in direct contact with the dielectric isolation structure.

Additional technical features and benefits are realized through the techniques of the present disclosure. Embodiments and aspects of this disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of this disclosure are apparent from the following detailed description taken in conjunction with the accompanying drawings in which:

FIG. 1A is a top-down reference view of a semiconductor wafer according to one or more embodiments;

FIGS. 1B, 1C, and 1D depict cross-sectional views of the semiconductor wafer of FIG. 1A taken along the lines X1, X2, and Y, respectively, after a processing operation according to one or more embodiments;

FIGS. 2A, 2B, and 2C depict cross-sectional views of the semiconductor wafer of FIG. 1A taken along the lines X1, X2, and Y, respectively, after a processing operation according to one or more embodiments;

FIGS. 3A, 3B, and 3C depict cross-sectional views of the semiconductor wafer of FIG. 1A taken along the lines X1, X2, and Y, respectively, after a processing operation according to one or more embodiments;

FIGS. 4A, 4B, and 4C depict cross-sectional views of the semiconductor wafer of FIG. 1A taken along the lines X1, X2, and Y, respectively, after a processing operation according to one or more embodiments;

FIGS. 5A, 5B, and 5C depict cross-sectional views of the semiconductor wafer of FIG. 1A taken along the lines X1, X2, and Y, respectively, after a processing operation according to one or more embodiments;

FIGS. 6A, 6B, and 6C depict cross-sectional views of the semiconductor wafer of FIG. 1A taken along the lines X1, X2, and Y, respectively, after a processing operation according to one or more embodiments;

FIGS. 7A, 7B, and 7C depict cross-sectional views of the semiconductor wafer of FIG. 1A taken along the lines X1, X2, and Y, respectively, after a processing operation according to one or more embodiments;

FIGS. 8A, 8B, and 8C depict cross-sectional views of the semiconductor wafer of FIG. 1A taken along the lines X1, X2, and Y, respectively, after a processing operation according to one or more embodiments;

FIGS. 9A, 9B, and 9C depict cross-sectional views of the semiconductor wafer of FIG. 1A taken along the lines X1, X2, and Y, respectively, after a processing operation according to one or more embodiments;

FIGS. 10A, 10B, and 10C depict cross-sectional views of the semiconductor wafer of FIG. 1A taken along the lines X1, X2, and Y, respectively, after a processing operation according to one or more embodiments;

FIGS. 11A, 11B, and 11C depict cross-sectional views of an alternative embodiment of the semiconductor wafer of FIG. 1A taken along the lines X1, X2, and Y, respectively, after a processing operation according to one or more embodiments;

FIGS. 12A, 12B, and 12C depict cross-sectional views of the alternative embodiment of the semiconductor wafer of FIG. 1A taken along the lines X1, X2, and Y, respectively, after a processing operation according to one or more embodiments;

FIGS. 13A, 13B, and 13C depict cross-sectional views of the alternative embodiment of the semiconductor wafer of FIG. 1A taken along the lines X1, X2, and Y, respectively, after a processing operation according to one or more embodiments;

FIGS. 14A, 14B, and 14C depict cross-sectional views of the alternative embodiment of the semiconductor wafer of FIG. 1A taken along the lines X1, X2, and Y, respectively, after a processing operation according to one or more embodiments;

FIGS. 15A, 15B, and 15C depict cross-sectional views of the alternative embodiment of the semiconductor wafer of FIG. 1A taken along the lines X1, X2, and Y, respectively, after a processing operation according to one or more embodiments; and

FIG. 16 depicts a flow diagram illustrating a method according to one or more embodiments.

The diagrams depicted herein are illustrative. There can be many variations to the diagram or the operations described therein without departing from the spirit of this disclosure. For instance, the actions can be performed in a differing order or actions can be added, deleted or modified.

In the accompanying figures and following detailed description of the described embodiments of this disclosure, the various elements illustrated in the figures are provided with two or three-digit reference numbers. With minor exceptions, the leftmost digit(s) of each reference number correspond to the figure in which its element is first illustrated.

### DETAILED DESCRIPTION

It is understood in advance that although example embodiments of the present disclosure are described in connection with a particular transistor architecture, embodiments are not limited to the particular transistor architectures or materials described in this specification. Rather, embodiments of the present disclosure are capable of being implemented in conjunction with any other type of transistor architecture or materials now known or later developed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the present disclosure, ICs are fabricated in a series of stages, including a front-end-of-line (FEOL) stage, a middle-of-line (MOL) stage, and a back-end-of-line (BEOL) stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts (e.g., CA) and other structures that communicatively couple to active regions (e.g., gate, source, and drain) of the device element. For example, the silicidation of source/drain regions, as well as the deposition of metal contacts, can occur during the MOL stage to connect the elements patterned during the FEOL stage. Layers of interconnections (e.g., metallization layers) are formed above these logical and functional layers during the BEOL stage to complete the IC. Most ICs need more than one layer of wires to form all the necessary connections, and as many as 5-12 layers are added in the BEOL process. The various BEOL layers are interconnected by vias that couple from one layer to another. Insulating dielectric materials are used throughout the layers of an IC to perform a variety of functions, including stabilizing the IC structure and providing electrical isolation of the IC elements. For example, the metal interconnecting wires in the BEOL region of the IC are isolated by dielectric layers to prevent the wires from creating a short circuit with other metal layers.

There are several nonplanar transistor architectures for scaling transistors beyond the 7 nm node, but each is currently limited due to various factors. One such architecture is the so-called stacked field effect transistor (FET). To increase the available computing power per unit area, stacked FET devices (or SFETs) vertically stack two (or more) FETs over a shared substrate footprint. The resultant stacked transistor architecture offers several improvements over planar and fin-type devices, such as the ability to build complementary devices (e.g., CMOS) at a reduced footprint. SFET fabrication is challenging, however, and efforts are ongoing to design SFET fabrication schemes and structures that are suitable for scaled production.

Monolithic SFET formation, for example, builds two (or more) FETs monolithically, that is, continuously from a common stack of semiconductor and sacrificial layers. This is in contrast to other SFET formation techniques, where two wafers are processed separately (i.e., semiconductor stacks are built on each wafer) and later joined via a wafer bonding process. For monolithic SFET formation, some of the key challenges are providing a wider separation between the top FET and the bottom FET, reducing direct facing gate-to-contact capacitance on the top FET, and providing enough (as wide as possible) of a contact interface to the bottom FET.

Turning now to an overview of aspects of the present disclosure, one or more embodiments address the above-described shortcomings by providing monolithic SFET fabrication methods and resulting structures for an L-shaped stacked field effect transistor (SFET) with separate top and bottom self-aligned contact (SAC) caps. As used herein, an “L-shaped” SFET refers to a configuration whereby a portion of the gate of the top FET over the bottom channel shoulder is removed (thus defining an L-shaped geometry), reducing direct facing capacitance. Moreover, rather than relying on a single SAC cap, the L-shaped SFET described herein leverages separate top and bottom SAC caps, with the bottom SAC cap at a lower elevation than the top SAC cap. While single SAC caps place native constraints on contact widths due to the high aspect ratios and geometries required to serve both the bottom FET and top FET, separate top and bottom SAC caps frees the bottom SAC cap from top SAC cap requirements, allowing for a relatively wider bottom contacts. Thus, an L-shaped SFET with separate top and bottom SAC caps directly addresses several of the current challenges facing monolithic SFET formation.

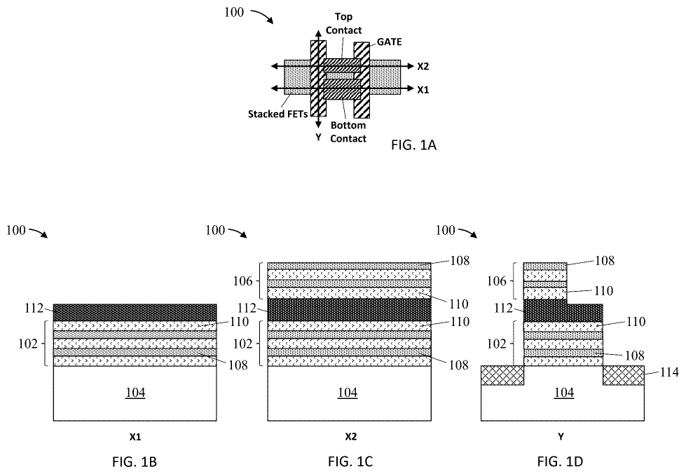

Turning now to a more detailed description of fabrication operations and resulting structures according to aspects of this disclosure, FIG. 1A depicts a reference top-down view of a semiconductor wafer 100 after fabrication operations have been applied as part of a method of fabricating a final semiconductor device according to one or more embodiments. FIG. 1B depicts a cross-sectional view taken along the line X1 (across gate below bottom contact) in FIG. 1A. FIG. 1C depicts a cross-sectional view taken along the line X2 (across gas below top contact) in FIG. 1A. FIG. 1D depicts a cross-sectional view taken along the line Y (along gate) in FIG. 1B.

As shown in FIGS. 1B, 1C, and 1D, a first nanosheet stack 102 is formed over a substrate 104 and a second nanosheet stack 106 is formed over the first nanosheet stack 102. The first nanosheet stack 102 and the second nanosheet stack 106 are together formed over a substrate 104. In some embodiments, the first nanosheet stack 102 and the second nanosheet stack 106 each include one or more nanosheets 108 alternating with one or more sacrificial layers 110. In some embodiments, the nanosheets 108 and the sacrificial layers 110 are epitaxially grown layers. For ease of discussion reference is made to operations performed on and to nanosheet stacks having two nanosheets (e.g., the (two) nanosheets 108 of the first nanosheet stack 102 and the second nanosheet stack 106, respectively, as shown in FIG. 1A) alternating with two sacrificial layers (e.g., the (two) sacrificial layers 110 of the second nanosheet stack 106) or three sacrificial layers (e.g., the three sacrificial layers 110 of the first nanosheet stack 102). It is understood, however, that the first nanosheet stack 102 and the second nanosheet stack 106 can include any number of nanosheets alternating with a corresponding number of sacrificial layers, as desired. For example, the first and second nanosheet stacks 102, 106 can include two nanosheets, five nanosheets, eight nanosheets, 30 nanosheets (e.g., 3D NAND), or any number of nanosheets, along with a corresponding number of sacrificial layers. Moreover, it is not necessary that the first nanosheet stack 102 and the second nanosheet stack 106 have a same number of nanosheets 108, and other configurations having any distribution of nanosheets is within the contemplated scope of this disclosure.

The nanosheets 108 and the substrate 104 can be made of any suitable semiconductor material, such as, for example, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlInAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys. The nanosheets 108 and the substrate 104 can be made of the same, or different, semiconductor materials. In some embodiments, the nanosheets 108 have a thickness of about 5 nm to about 15 nm, for example 10 nm, although other thicknesses are within the contemplated scope of this disclosure.

In some embodiments, the substrate 104 is structured as a silicon-on-insulator (SOI) substrate having a buried oxide layer (not separately indicated). The buried oxide layer can be made of any suitable material, such as, for example, silicon oxide (SiO₂) or silicon germanium. In some embodiments, the buried oxide layer is formed to a thickness of about 10-200 nm, although other thicknesses are within the contemplated scope of this disclosure.

The sacrificial layers 110 can made of silicon, silicon germanium, or other semiconductor materials, depending on the material of the nanosheets 108, to meet etch selectivity requirements. For example, in embodiments where the nanosheets 108 are silicon nanosheets, the sacrificial layers 110 can be silicon germanium layers. In embodiments where the nanosheets 108 are silicon germanium nanosheets, the sacrificial layers 110 can be silicon layers or silicon germanium layers having a germanium concentration that is greater than the germanium concentration in the nanosheets 108. For example, if the nanosheets 108 are silicon germanium having a germanium concentration of 5 percent (sometimes referred to as SiGe5), the sacrificial layers 110 can be silicon germanium layers having a germanium concentration of 25 percent (SiGe25), although other germanium concentrations are within the contemplated scope of this disclosure. In some embodiments, the sacrificial layers 110 have a thickness of about 5 nm to about 12 nm, for example 10 nm, although other thicknesses are within the contemplated scope of this disclosure.

In some embodiments, the first nanosheet stack 102 and the second nanosheet stack 106 are separated by an isolation placeholder layer 112. The isolation placeholder layer 112 can be made of similar materials as sacrificial layers 110, although materials for the isolation placeholder layer 112 are selected to ensure etch selectivity with respect to the nanosheets 108 and the sacrificial layers 110. For example, in embodiments where the nanosheets 108 are silicon nanosheets and the sacrificial layers 110 are SiGe25 layers, the isolation placeholder layer 112 can be SiGe50 layers, although other germanium concentrations are within the contemplated scope of this disclosure. In some embodiments, the isolation placeholder layer 112 is formed to a thickness of 15 to 100 nm, for example 50 nm, although other thicknesses are within the contemplated scope of this disclosure.

As shown in FIG. 1B, the second nanosheet stack 106 can be removed from some regions of the semiconductor wafer 100. In some embodiments, portions of the second nanosheet stack 106 can removed to expose a surface of isolation placeholder layer 112. Any known method for patterning nanosheet stacks can be used, such as, for example, a wet etch, a dry etch, or a combination of sequential wet and/or dry etches.

As shown in FIG. 1D, the first nanosheet stack 102 and the second nanosheet stack 106 can be patterned in a process referred to as nanosheet patterning. In some embodiments, portions of the first nanosheet stack 102 and the second nanosheet stack 106 are removed to expose a surface of the substrate 104, which is then recessed to define a cavity (not separately shown). A shallow trench isolation (STI) region 114 can be formed by refilling the cavity with dielectrics, such as, for example, silicon oxide, silicon nitride, silicon carbide, hydrogenated silicon carbonitrides, silicon oxynitrides, and silicon borocarbonitrides, although other dielectrics are within the contemplated scope of this disclosure.

As further shown in FIG. 1D, in some embodiments, additional portions of the second nanosheet stack 106 are removed to expose a surface of isolation placeholder layer 112. Any known method for patterning nanosheet stacks can be used, such as, for example, a wet etch, a dry etch, or a combination of sequential wet and/or dry etches.

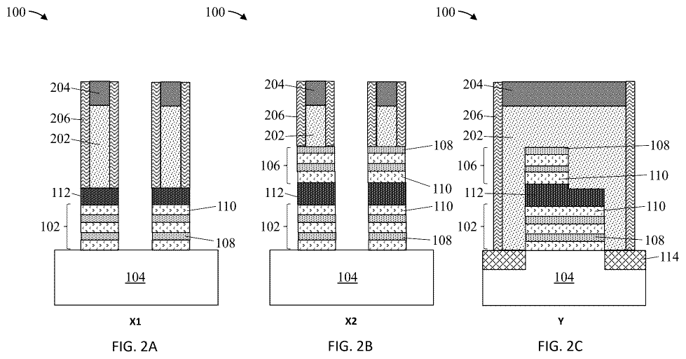

FIGS. 2A, 2B, and 2C depict cross-sectional views of the semiconductor wafer 100 of FIG. 1A taken along the lines X1, X2, and Y, respectively, after a processing operation according to one or more embodiments. In some embodiments, one or more sacrificial gates 202 (sometimes referred to as dummy gates) are formed and patterned over channel regions of the first nanosheet stack 102 and the second nanosheet stack 106. As used herein, a “channel region” refers to a portion of a nanosheet over which a conductive gate (described in further detail later) is formed, and through which current passes from source to drain in a final device. The sacrificial gate 202 can be made of any suitable material, such as, for example, amorphous silicon or polysilicon. Any known method for patterning a sacrificial gate can be used, such as, for example, a wet etch, a dry etch, or a combination of sequential wet and/or dry etches. In some embodiments, a hard mask 204 is formed on the sacrificial gate 202. The hard mask 204 can be made of any suitable materials, such as, for example, silicon nitride.

In some embodiments, gate spacers 206 are formed on sidewalls of the sacrificial gate 202. This process can be referred to as the gate spacer module. The gate spacers 206 can be made of any suitable dielectric material, such as, for example, silicon oxide, silicon nitride, silicon carbide, hydrogenated silicon carbonitrides, silicon oxynitrides, and silicon borocarbonitrides, although other dielectrics are within the contemplated scope of this disclosure. In some embodiments, spacer material is deposited conformally (not separately shown) over the semiconductor wafer 100 and patterned using an anisotropic etch, for example, a reactive ion etch (RIE).

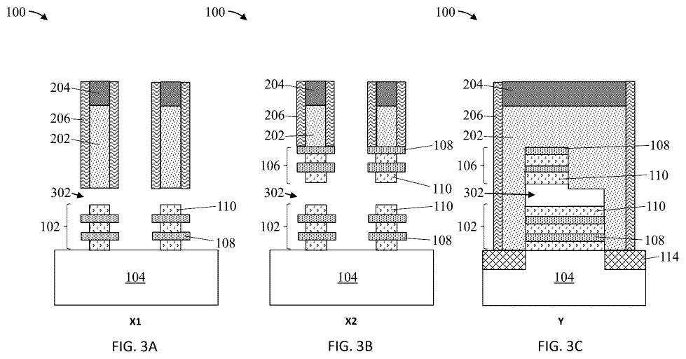

FIGS. 3A, 3B, and 3C depict cross-sectional views of the semiconductor wafer 100 of FIG. 1A taken along the lines X1, X2, and Y, respectively, after a processing operation according to one or more embodiments. In some embodiments, the isolation placeholder layer 112 is removed and the sacrificial layers 110 are recessed, defining cavities 302. The isolation placeholder layer 112 can be removed concurrently and/or separately from recessing the sacrificial layers 110. In some embodiments, the isolation placeholder layer 112 is removed and the sacrificial layers 110 are recessed using, for example, a wet etch, a dry etch, or a combination of sequential wet and/or dry etches. In some embodiments, the isolation placeholder layer 112 is removed and the sacrificial layers 110 are recessed selective to the nanosheets 108.

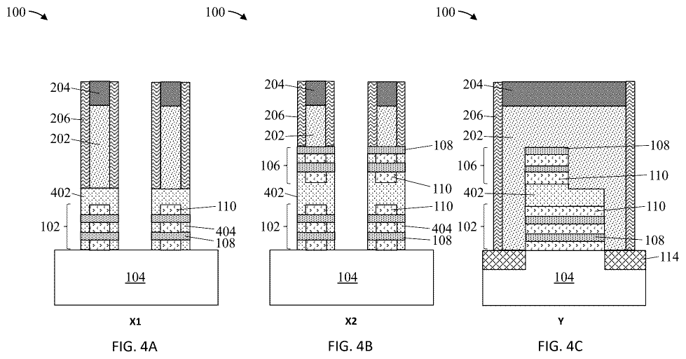

FIGS. 4A, 4B, and 4C depict cross-sectional views of the semiconductor wafer 100 of FIG. 1A taken along the lines X1, X2, and Y, respectively, after a processing operation according to one or more embodiments. In some embodiments, the cavities 302 are filled with dielectrics, defining an isolation structure 402 and inner spacers 404. The dielectric materials for the isolation structure 402 and inner spacers 404 can include, for example, silicon oxide, silicon nitride, silicon carbide, hydrogenated silicon carbonitrides, silicon oxynitrides, and silicon borocarbonitrides, although other dielectrics are within the contemplated scope of this disclosure. In some embodiments, dielectric material is deposited conformally (not separately shown) over the semiconductor wafer 100 and patterned using an anisotropic etch, for example, a reactive ion etch (RIE) to define the isolation structure 402 and inner spacers 404.

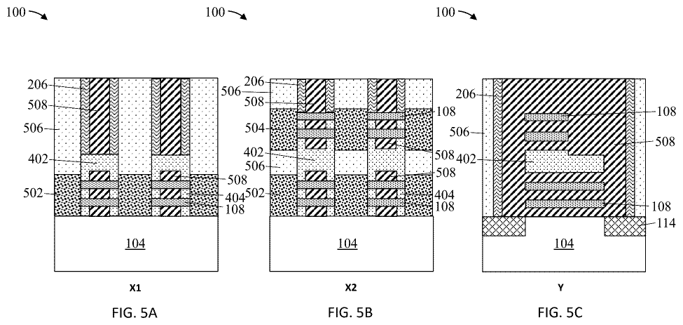

FIGS. 5A, 5B, and 5C depict cross-sectional views of the semiconductor wafer 100 of FIG. 1A taken along the lines X1, X2, and Y, respectively, after a processing operation according to one or more embodiments. In some embodiments, FEOL fabrication processes are used to form bottom source/drain regions 502, top source/drain regions 504, and an interlayer dielectric (ILD) 506 between the top source/drain regions 504 and the bottom source/drain regions 502.

In some embodiments, the bottom source/drain regions 502 are epitaxially grown or otherwise formed on an exposed surface of the substrate 104 after recessing the first nanosheet stack 102 and the second nanosheet stack 106. In addition, or alternatively, the bottom source/drain regions 502 can be epitaxially grown from exposed sidewalls of the nanosheets 108.

In some embodiments, the ILD 506 is formed by depositing otherwise forming dielectric material between and over the bottom source/drain regions 502 and the top source/drain regions 504. The ILD 506 can be made of any suitable dielectric material, such as, for example, oxides, a low-k dielectric, nitrides, silicon nitride, silicon oxide, SiON, SiC, SiOCN, and SiBCN.

In some embodiments, the top source/drain regions 504 are formed on a surface of the ILD 506. In some embodiments, the top source/drain regions 504 can be epitaxially grown from exposed sidewalls of the nanosheets 108, in a similar manner as described previously with respect to the bottom source/drain regions 502.

As further shown in FIGS. 5A, 5B, and 5C, the semiconductor wafer 100 can be polished (planarized) to remove the hard mask 204. The semiconductor wafer 100 can be polished using any suitable method, such as, for example, chemical mechanical planarization (CMP). In some embodiments, the semiconductor wafer 100 can be polished to a surface of the sacrificial gate 202 (refer to FIGS. 4A, 4B, and 4C). In some embodiments, the sacrificial gate 202 and the sacrificial layers 110, 120 are removed to release the nanosheets 108. The sacrificial gate 202 can be removed using a wet etch, a dry etch, or a combination of sequential wet and/or dry etches.

The sacrificial gate 202 and/or sacrificial layers 110 can be removed selective to the nanosheets 108. For example, when the nanosheets 108 are formed of silicon and the sacrificial layers 110 are formed of silicon germanium, hydrogen chloride (HCl) gas, or an aqueous solution containing a mix of ammonia and hydrogen peroxide, can be utilized to remove silicon germanium selective to silicon. In another example, when the nanosheets 108 are formed of silicon germanium and the sacrificial layers 110 are formed of silicon, aqueous hydroxide chemistry, including ammonium hydroxide and potassium hydroxide, can be utilized to remove silicon selective to silicon germanium.

In some embodiments, the (removed) sacrificial gate 202 (refer to FIGS. 4A, 4B, and 4C) can be replaced with a conductive gate 508. The conductive gate 508 can be a high-k metal gate (HKMG) formed over channel regions of the first nanosheet stack 102 and the second nanosheet stack 106 using, for example, known replacement metal gate (RMG) processes, or so-called gate-last processes. In some embodiments, the conductive gate 508 can include a gate dielectric and a work function metal stack (not separately depicted). While shown as a single gate (i.e., a common gate stack) for ease of illustration and discussion, it should be understood that the conductive gate 508 can include separate gate portions for the first nanosheet stack 102 and the second nanosheet stack 106. That is, in some embodiments, each gate portion can be electrically isolated from the other(s) using, e.g., one or more interlayer dielectric layers (not separately shown).

In some embodiments, the gate dielectric is a high-k dielectric film formed on a surface (sidewall) of the nanosheets 108. The high-k dielectric film can be made of, for example, silicon oxide, silicon nitride, silicon oxynitride, boron nitride, high-k materials, or any combination of these materials. Examples of high-k materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k materials can further include dopants such as lanthanum and aluminum. In some embodiments, the high-k dielectric film can have a thickness of about 0.5 nm to about 4 nm. In some embodiments, the high-k dielectric film includes hafnium oxide and has a thickness of about 1 nm, although other thicknesses are within the contemplated scope of this disclosure.

The work function metal stack, if present, can include one or more work function layers positioned between the high-k dielectric film and a bulk gate material. In some embodiments, the conductive gate 508 includes one or more work function layers, but does not include a bulk gate material. The work function layers can be made of, for example, aluminum, lanthanum oxide, magnesium oxide, strontium titanate, strontium oxide, titanium nitride, tantalum nitride, hafnium nitride, tungsten nitride, molybdenum nitride, niobium nitride, hafnium silicon nitride, titanium aluminum nitride, tantalum silicon nitride, titanium aluminum carbide, tantalum carbide, and combinations thereof. The work function layers can serve to modify the work function of the conductive gate 508 and enables tuning of the device threshold voltage. The work function layers can be formed to a thickness of about 0.5 to 6 nm, although other thicknesses are within the contemplated scope of this disclosure. In some embodiments, each of the work function layers can be formed to a different thickness.

In some embodiments, the conductive gate 508 includes a main body formed from bulk conductive gate material(s) deposited over the work function layers and/or gate dielectrics. The bulk gate material can include any suitable conducting material, such as, for example, metal (e.g., tungsten, titanium, tantalum, ruthenium, zirconium, cobalt, copper, aluminum, lead, platinum, tin, silver, gold), conducting metallic compound material (e.g., tantalum nitride, titanium nitride, tantalum carbide, titanium carbide, titanium aluminum carbide, tungsten silicide, tungsten nitride, ruthenium oxide, cobalt silicide, nickel silicide), conductive carbon, graphene, or any suitable combination of these materials. The conductive gate materials can further include dopants that are incorporated during or after deposition.

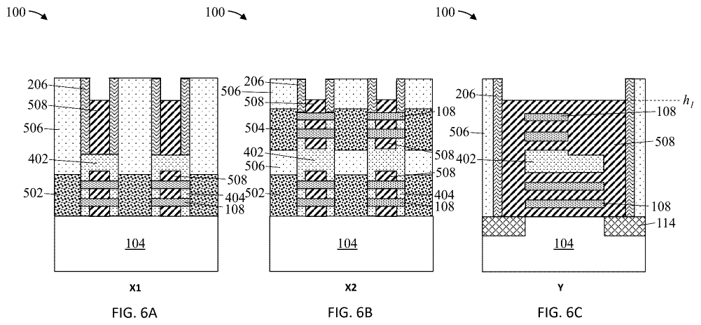

FIGS. 6A, 6B, and 6C depict cross-sectional views of the semiconductor wafer 100 of FIG. 1A taken along the lines X1, X2, and Y, respectively, after a processing operation according to one or more embodiments. In some embodiments, portions of the conductive gate 508 are recessed to define a first gate height h₁. Any known method for patterning gates can be used, such as, for example, a wet etch, a dry etch, or a combination of sequential wet and/or dry etches.

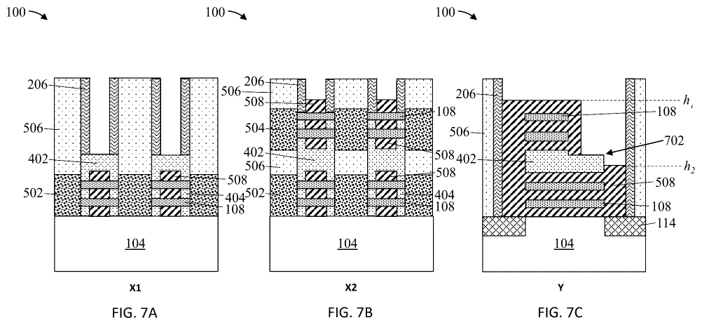

FIGS. 7A, 7B, and 7C depict cross-sectional views of the semiconductor wafer 100 of FIG. 1A taken along the lines X1, X2, and Y, respectively, after a processing operation according to one or more embodiments. In some embodiments, portions of the conductive gate 508 are further recessed to define a second gate height h₂. Any known method for patterning gates can be used, such as, for example, a wet etch, a dry etch, or a combination of sequential wet and/or dry etches. In some embodiments, this further gate recess exposes a shoulder surface 702 of the isolation structure 402.

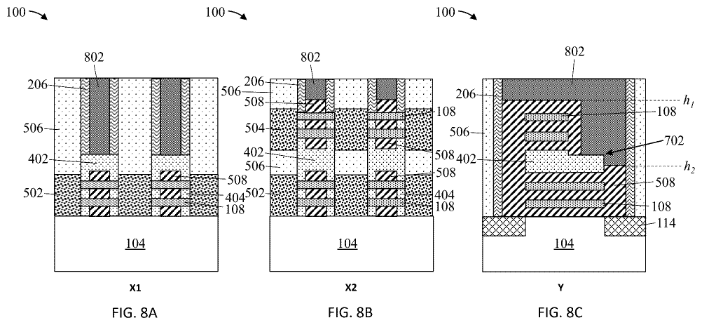

FIGS. 8A, 8B, and 8C depict cross-sectional views of the semiconductor wafer 100 of FIG. 1A taken along the lines X1, X2, and Y, respectively, after a processing operation according to one or more embodiments. In some embodiments, dielectrics 802 are deposited over or otherwise formed on the recessed portions of the conductive gate 508. The dielectric materials can include, for example, silicon oxide, silicon nitride, silicon carbide, hydrogenated silicon carbonitrides, silicon oxynitrides, and silicon borocarbonitrides, although other dielectrics are within the contemplated scope of this disclosure.

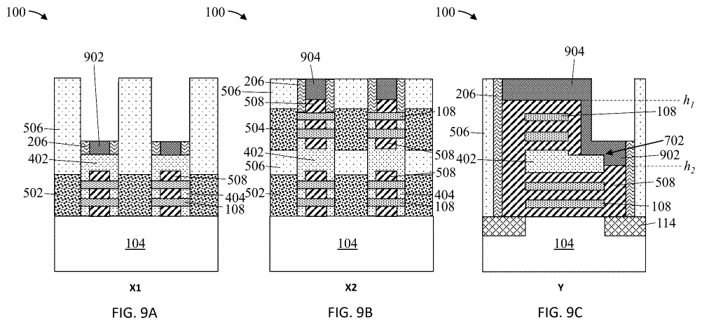

FIGS. 9A, 9B, and 9C depict cross-sectional views of the semiconductor wafer 100 of FIG. 1A taken along the lines X1, X2, and Y, respectively, after a processing operation according to one or more embodiments. In some embodiments, dielectrics 802 are selectively recessed to define bottom SAC caps 902 and top SAC caps 904. Any known method for patterning dielectrics can be used, such as, for example, a wet etch, a dry etch, or a combination of sequential wet and/or dry etches. Observe that the bottom SAC caps 902 and top SAC caps 904 are formed at different elevations within semiconductor wafer 101. In particular, the bottom SAC caps 902 are formed on the conductive gate 508 where the conductive gate 508 is recessed to the second gate height h₂. Conversely, top SAC caps 904 are formed on the conductive gate 508 where the conductive gate 508 is recessed to the first gate height h₁.

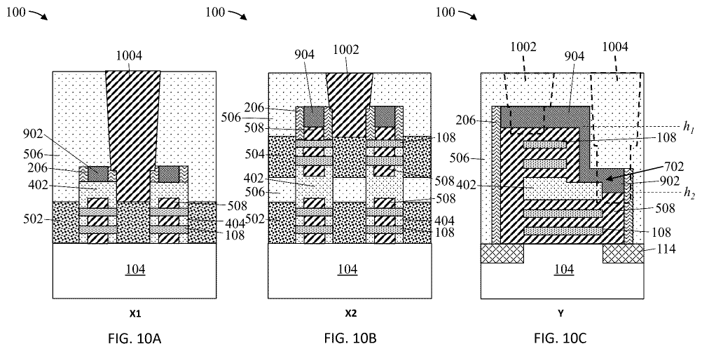

FIGS. 10A, 10B, and 10C depict cross-sectional views of the semiconductor wafer 100 of FIG. 1A taken along the lines X1, X2, and Y, respectively, after a processing operation according to one or more embodiments. In some embodiments, FEOL and MOL fabrication operations are used to extend the ILD 506 with the same or different dielectrics and to form contacts to various device substructures, such as a top contact 1002, sometimes referred to as the top epitaxy contact or the shallow contact, a bottom contact 1004, sometimes referred to as the bottom epitaxy contact or the deep contact, and one or more gate contacts (not separately shown).

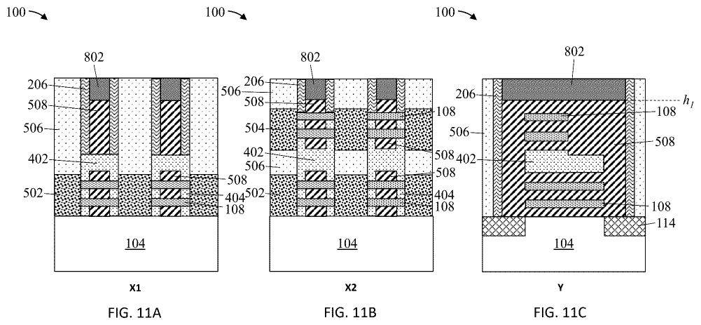

FIGS. 11A, 11B, and 11C depict cross-sectional views of an alternative embodiment of the semiconductor wafer 100 of FIG. 1A taken along the lines X1, X2, and Y, respectively, after a processing operation according to one or more embodiments. The processing operation shown in FIGS. 11A, 11B, and 11C largely follow those previously described with respect to FIGS. 6A, 6B, and 6C. In some embodiments, portions of the conductive gate 508 are recessed to define a first gate height h₁. Any known method for patterning gates can be used, such as, for example, a wet etch, a dry etch, or a combination of sequential wet and/or dry etches.

In some embodiments, dielectrics 802 are deposited over or otherwise formed on the recessed portions of the conductive gate 508. The dielectric materials can include, for example, silicon oxide, silicon nitride, silicon carbide, hydrogenated silicon carbonitrides, silicon oxynitrides, and silicon borocarbonitrides, although other dielectrics are within the contemplated scope of this disclosure.

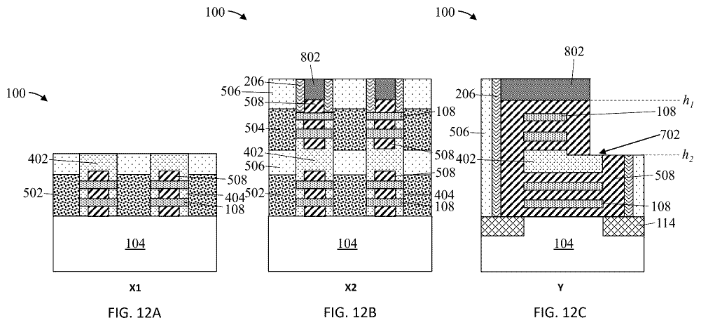

FIGS. 12A, 12B, and 12C depict cross-sectional views of the alternative embodiment of the semiconductor wafer 100 of FIG. 1A taken along the lines X1, X2, and Y, respectively, after a processing operation according to one or more embodiments. In some embodiments, portions of the semiconductor wafer 100 are removed to expose a surface of the isolation structure 402 (refer to FIGS. 12A and 12C). In some embodiments, portions of the conductive gate 508 are further recessed to define a second gate height h₂. Any known method for patterning gates can be used, such as, for example, a wet etch, a dry etch, or a combination of sequential wet and/or dry etches. In some embodiments, this further gate recess exposes a shoulder surface 702 of the isolation structure 402.

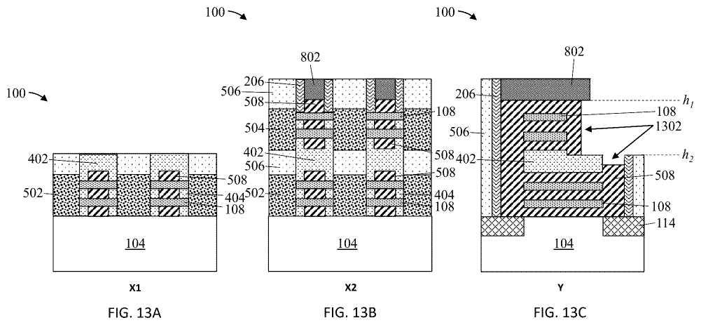

FIGS. 13A, 13B, and 13C depict cross-sectional views of the alternative embodiment of the semiconductor wafer 100 of FIG. 1A taken along the lines X1, X2, and Y, respectively, after a processing operation according to one or more embodiments. In some embodiments, the conductive gate 508 is recessed back selective to the dielectrics 802, isolation structure 402, and/or gate spacers 206, thereby defining disjoint L-shaped gate cavities 1302.

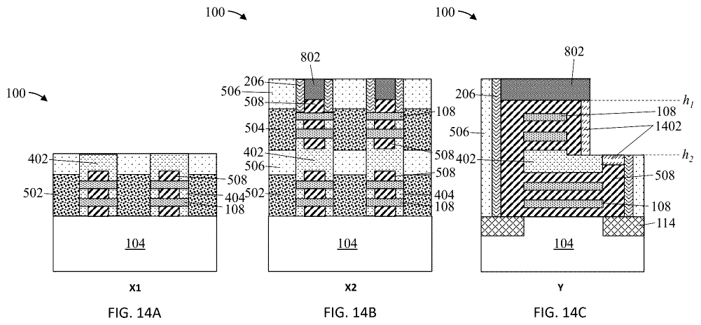

FIGS. 14A, 14B, and 14C depict cross-sectional views of the alternative embodiment of the semiconductor wafer 100 of FIG. 1A taken along the lines X1, X2, and Y, respectively, after a processing operation according to one or more embodiments. In some embodiments, the disjoint L-shaped gate cavities 1302 are filled with dielectrics, defining a disjoint L-shaped isolation structure 1402. The dielectric materials for the disjoint L-shaped isolation structure 1402 can include, for example, silicon oxide, silicon nitride, silicon carbide, hydrogenated silicon carbonitrides, silicon oxynitrides, and silicon borocarbonitrides, although other dielectrics are within the contemplated scope of this disclosure. In some embodiments, dielectric material is deposited conformally (not separately shown) over the semiconductor wafer 100 and patterned using an anisotropic etch, for example, a reactive ion etch to define the disjoint L-shaped isolation structure 1402.

After backside processing is complete, the semiconductor wafer 100 can be finalized using known processes (e.g., additional BEOL processing, including the incorporation of any number of interconnections and metallization layers, far back end of line (FBEOL) processing, packaging module(s), etc.) to define a final device.

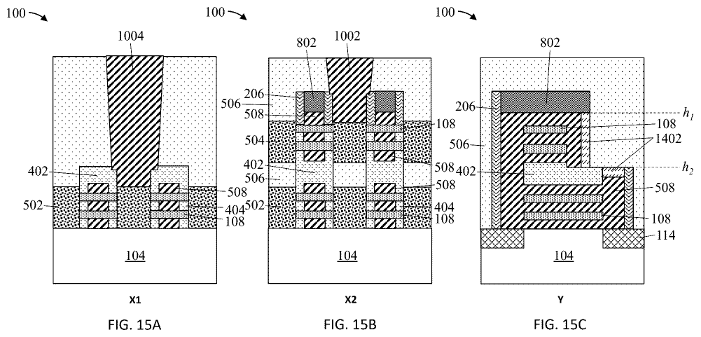

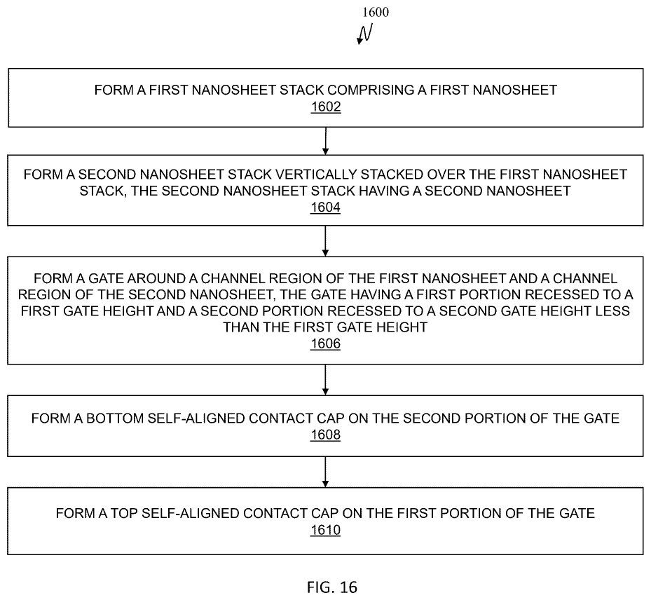

FIG. 16 depicts a flow diagram illustrating a method 1600 for providing an L-shaped SFET with separate top and bottom SAC caps according to one or more embodiments. The method 1600 is described in reference to FIGS. 1A-15C and may include additional blocks not depicted in FIG. 16. Although depicted in a particular order, the blocks depicted in FIG. 16 can be rearranged, subdivided, and/or combined.

As shown at block 1602, the method includes forming a first nanosheet stack having a first nanosheet.

As shown at block 1604, the method includes forming a second nanosheet stack vertically stacked over the first nanosheet stack. The second nanosheet stack includes a second nanosheet.

As shown at block 1606, the method includes forming a gate around a channel region of the first nanosheet and a channel region of the second nanosheet. In some embodiments, the gate includes a first portion recessed to a first gate height and a second portion recessed to a second gate height less than the first gate height.

As shown at block 1608, the method includes forming a bottom self-aligned contact cap on the second portion of the gate.

As shown at block 1610, the method includes forming a top self-aligned contact cap on the first portion of the gate.

In some embodiments, the first nanosheet stack further includes one or more additional nanosheets, and the second nanosheet stack further includes one or more additional nanosheets.

In some embodiments, the method includes forming a dielectric isolation structure between the first nanosheet stack and the second nanosheet stack.

In some embodiments, the method includes forming a bottom source or drain region in direct contact with sidewalls of the first nanosheet and forming a top source or drain region in direct contact with sidewalls of the second nanosheet. In some embodiments, the bottom source or drain region is electrically isolated from the top source or drain region. In some embodiments, the first source or drain region includes a first doping type and the second source or drain region includes a second doping type opposite the first doping type.

In some embodiments, the method includes forming a bottom contact on a surface of the bottom source or drain region and forming a top contact on a surface of the top source or drain region.

In some embodiments, the gate is recessed to define a disjoint L-shaped cavity. In some embodiments, the method includes forming a disjoint L-shaped isolation structure in the disjoint L-shaped cavity. In some embodiments, disjoint portions of the disjoint L-shaped isolation structure are in direct contact with the dielectric isolation structure.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Similarly, the term “coupled” and variations thereof describes having a communications path between two elements and does not imply a direct connection between the elements with no intervening elements/connections between them. All of these variations are considered a part of the specification. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, are used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (e.g., rotated 90 degrees or at other orientations), and the spatially relative descriptors used herein should be interpreted accordingly.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The phrase “selective to,” such as, for example, “a first element selective to a second element,” means that the first element can be etched and the second element can act as an etch stop (i.e., the second element remains).

The term “conformal” (e.g., a conformal layer or a conformal deposition) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a <100> orientated crystalline surface can take on a <100> orientation. In some embodiments, epitaxial growth and/or deposition processes can be selective to forming on semiconductor surface, and may or may not deposit material on other exposed surfaces, such as silicon dioxide or silicon nitride surfaces.

As used herein, “p-type” refers to the addition of impurities to an intrinsic semiconductor that creates deficiencies of valence electrons. In a silicon-containing substrate, examples of p-type dopants, i.e., impurities, include but are not limited to, boron, aluminum, gallium, and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments described herein can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method for forming a semiconductor device, the method comprising:
forming a first nanosheet stack comprising a first nanosheet;
forming a second nanosheet stack vertically stacked over the first nanosheet stack, the second nanosheet stack comprising a second nanosheet;
forming a gate around a channel region of the first nanosheet and a channel region of the second nanosheet, the gate having a first portion recessed to a first gate height and a second portion recessed to a second gate height less than the first gate height;
forming a bottom self-aligned contact cap on the second portion of the gate; and
forming a top self-aligned contact cap on the first portion of the gate.

2. The method of claim 1, wherein the first nanosheet stack further comprises one or more additional nanosheets, and wherein the second nanosheet stack further comprises one or more additional nanosheets.

3. The method of claim 2, further comprising a dielectric isolation structure between the first nanosheet stack and the second nanosheet stack.

4. The method of claim 1, further comprising
a bottom source or drain region in direct contact with sidewalls of the first nanosheet; and
a top source or drain region in direct contact with sidewalls of the second nanosheet.

5. The method of claim 4, wherein the bottom source or drain region is electrically isolated from the top source or drain region.

6. The method of claim 5, wherein the bottom source or drain region comprises a first doping type and the top source or drain region comprises a second doping type opposite the first doping type.

7. The method of claim 4, further comprising
a bottom contact on a surface of the bottom source or drain region; and
a top contact on a surface of the top source or drain region.

8. The method of claim 3, wherein the gate is recessed to define a disjoint L-shaped cavity.

9. The method of claim 8, further comprising a disjoint L-shaped isolation structure in the disjoint L-shaped cavity.

10. The method of claim 9, wherein disjoint portions of the disjoint L-shaped isolation structure are in direct contact with the dielectric isolation structure.

11. A semiconductor device comprising:
a first nanosheet stack comprising a first nanosheet;
a second nanosheet stack vertically stacked over the first nanosheet stack, the second nanosheet stack comprising a second nanosheet;
a gate formed around a channel region of the first nanosheet and a channel region of the second nanosheet, the gate having a first portion recessed to a first gate height and a second portion recessed to a second gate height less than the first gate height;
a bottom self-aligned contact cap formed on the second portion of the gate; and
a top self-aligned contact cap formed on the first portion of the gate.

12. The semiconductor device of claim 11, wherein the first nanosheet stack further comprises one or more additional nanosheets, and wherein the second nanosheet stack further comprises one or more additional nanosheets.

13. The semiconductor device of claim 12, further comprising a dielectric isolation structure between the first nanosheet stack and the second nanosheet stack.

14. The semiconductor device of claim 11, further comprising
a bottom source or drain region in direct contact with sidewalls of the first nanosheet; and
a top source or drain region in direct contact with sidewalls of the second nanosheet.

15. The semiconductor device of claim 14, wherein the bottom source or drain region is electrically isolated from the top source or drain region.

16. The semiconductor device of claim 15, wherein the bottom source or drain region comprises a first doping type and the top source or drain region comprises a second doping type opposite the first doping type.

17. The semiconductor device of claim 14, further comprising
a bottom contact on a surface of the bottom source or drain region; and
a top contact on a surface of the top source or drain region.

18. The semiconductor device of claim 13, wherein the gate is recessed to define a disjoint L-shaped cavity.

19. The semiconductor device of claim 18, further comprising a disjoint L-shaped isolation structure in the disjoint L-shaped cavity.

20. The semiconductor device of claim 19, wherein disjoint portions of the disjoint L-shaped isolation structure are in direct contact with the dielectric isolation structure.
